(19) United States
(12) Patent Application Publication
(10) Pub. No.: US 2007/0098904 A1
(43) Pub. Date: May 3, 2007

(54) Device and method for the reduction of particles in the thermal treatment of rotating substrates

(76) Inventors: Helmut Aschner, Beimerstetten (DE); Patrick Schmid, Dornstadt (DE); Thomas Theiler, Ulm (DE); Ottmar Heudorfer, Warthausen (DE); Karsten Weber, Leutenbach (DE); Conor O'Carroll, Vancouver (CA)

Correspondence Address: DORITY & MANNING, P.A., POST OFFICE BOX 1449, GREENVILLE, SC, 29602-1449, US

(21) Appl. No.: 11/440,796

(22) Filed: May 25, 2006

Related U.S. Application Data
(60) Provisional application No. 60/696,876, filed on Jul. 6, 2005.

(30) Foreign Application Priority Data
May 25, 2005 (DE) 10 2005 024 118.2

(51) Int. Cl. B05D 3/02; H01L 21/00

(52) U.S. Cl. 427/372.2; 392/418; 392/416; 118/724

(57) ABSTRACT

A device and a method for reducing particle exposure to substrates during thermal treatment are disclosed. Semiconductor wafers may be rotated on a device within a process chamber divided into two partial chambers such that a first partial chamber contains the substrate to be thermally treated and a second partial chamber contains at least parts of the rotation device. Between the partial chambers, a flow of gas is set such that gas from the second partial chamber is substantially prevented from passing into the first partial chamber. In this way, particles which are produced by rotation abrasion in the second partial chamber are largely prevented from passing onto the substrate to be thermally treated. This device and this method are particularly advantageous if the rotation is realized by means of a gas drive, wherein the gas used for the rotation can be introduced directly into the second partial chamber.

### RELATED APPLICATIONS

The present application is based on and claims priority to U.S. Provisional Application No. 60/696,876, filed Jul. 6, 2005, and German Patent Application No. 10 2005 024 118.2, filed May 25, 2005.

### FIELD OF THE INVENTION

This invention relates to a device and a method for the thermal treatment of substrates, in particular semi-conductor wafers, in a process chamber, the substrate to be treated being rotated during thermal treatment within the process chamber.

### BACKGROUND OF THE INVENTION

Rapid heating units, so-called RTP systems for the thermal treatment of substrates, such as e.g. semi-conductor wafers, are well known in the production of semiconductors. Units of this type are described, for example, in U.S. Pat. No. 5,359,693 and U.S. Pat. No. 5,580,830. They are used for the thermal treatment of substrates, preferably wafers, which are preferably made of silicon, but also of other semi-conductor materials such as germanium, SiC or other connection semiconductors such as GaAs or InP. In these types of rapid heating unit, the wafers are subjected to thermal processes in different process gas atmospheres in order to achieve predetermined treatment results, such as for example doping of the wafer.

Rapid heating units must guarantee the highest possible output, and the components and integrated circuits produced must have reproducible characteristics. Rapid heating units which are used for the production of semiconductor wafers must therefore, among other things, fulfill the stringent requirements for the purity of the process gas atmosphere, show a high level of homogeneity with the thermal heating, and guarantee as far as possible freedom from particles on the substrate.

The local diffusion speed of doping materials in a wafer, and the quality of dielectric and conductive properties of layers on a wafer depend significantly upon the process temperature and upon the realization of the thermal process. The process should, for example, be realized such that particles which are located in the process chamber can not reach the substrate to be treated thermally, and this places special constraints upon the flow of gas. For example, particles located on the process chamber walls may be swirled about when process gas is introduced. The composition of the process gas atmosphere and the thermal homogeneity during the thermal treatment also considerably influence the process result.

A homogeneous temperature distribution over the wafer during a thermal treatment can often be improved in rapid heating units by allowing the substrate to rotate during the thermal process. This is generally brought about by placing the substrate on a rotation device located in the process chamber. The rotation device can also be transparent, and rotates during the thermal process. Preferably, the substrate is heated by means of optical radiation from both sides.

However, rotation produces mechanical abrasion, and therefore particles. One can try to reduce this problem by keeping the mechanical contact between the rotating elements of the rotation device and the fixed parts of the rotation device as small as possible, or by fitting ball bearings between rotating elements and fixed elements of the rotation device so that the friction between the elements is substantially restricted to a rolling friction. The weight of the rotating parts of the rotation device must also be kept as low as possible so as to minimize the mechanical abrasion. Despite this, the occurrence of particles caused by mechanical abrasion can not be avoided altogether.

It is therefore often tried to minimize the number of particles occurring as a result of abrasion by operating the rotation device with a gas such that a cushion of air is created between the fixed and the rotating elements of the rotation device, and the rotation on this cushion of air is also controlled with gas, i.e. set in motion, accelerated, and decelerated again, as described, for example, in U.S. Pat. No. 6,449,428.

Despite this, particles resulting from mechanical abrasion can not be totally prevented from passing into the process atmosphere. Even in the case of a gas-driven rotation, particles occur both at the start of the process, when the cushion of air forms and separates fixed and movable parts from one another, and after the end of the process, when the substrate is decelerated in the chamber again and the rotating parts of the rotation device are placed back on the fixed parts of the rotation device. These particles, together with particles which are already to be found on the floor or on the walls of the process chamber, can be swirled around by the gas flow of the rotation gas or by the process gas itself, and so reach the substrate to be treated thermally, and the overall result is a reduction in yield.

A further disadvantage of gas-driven arrangements is that rotation gas and process gas may mix together, and so have an unfavorable effect upon the process realization. The use of different gases and gas mixtures for the thermal process realization and for the rotation drive is often only possible to a limited degree when using a gas-driven rotation device. This is because any gas used for the rotation drive must not alter the composition of the process gas by mixing to such a degree that the resulting gas mixture results in a different process result. Therefore, the same gases must often be used for the rotation and for the process. Due to this, high additional costs often arise because expensive, very pure process gas must be used for the rotation and for the process.

Furthermore, it is often only possible to use the same gases or the same gas mixture for the rotation and for the process with very expensive additional devices. An example of this is wet oxidation, which is often used in semiconductor process technology. In such a process, nitrogen, oxygen and hydrogen, and water vapor are introduced into the process chamber along with the process gas or gasses. Water vapor condenses at temperatures below the boiling temperature for water, and therefore the feed pipes must be heated. With gas-driven rotation, this means considerably increased cost because, with excessively high concentrations, the water vapor would otherwise condense at parts of the rotation device. Therefore, the gas mixture used for the rotation often contains no, or only a very small amount of, water vapor. However, as a result the actual process gas can be diluted by the rotation gas such that the process gas cannot be maintained at the desired water vapor concentration. Moreover, it is difficult to always guarantee a constant water vapor concentration over the substrate to be heated because the flow of gas for the rotation is not constant during the process.

Even when using exactly the same gases or gas mixtures for the process and the rotation, between these gases, swirls and other non-laminar gas flows can occur in the process chamber which contains the substrate to be treated. Such gas flows may transport abrasion particles and can also separate particles from the wall surfaces and convey them to the substrate.

### SUMMARY OF THE INVENTION

Therefore, an object of this invention is to, in a simple and cost-effective way, prevent particles from reaching a substrate in a thermal treatment process.

This object is fulfilled with a rapid heating system for the thermal treatment of substrates with a process chamber for accommodating the substrate, at least one heating source for heating the substrate, a rotation device for holding and rotating the substrate, at least one gas inlet for admitting process gas into the process chamber, and at least one gas outlet for discharging gas from the process chamber, such that at least one separation element is provided in the process chamber which divides the process chamber into at least two partial chambers such that a first partial chamber fully encloses the substrate to be treated thermally, and a second partial chamber encloses at least a part of the rotation device, the first and the second partial chambers being connected at least by means of an air gap which is formed between the separation element and at least one rotating element of the rotation device, the at least one gas inlet being open to the first partial chamber, and the at least one gas outlet being open to the second partial chamber.

This type of device makes it possible for a first chamber for accommodating the substrate to be treated and a second chamber for at least partially accommodating the rotation device within a process chamber to be substantially separated from one another so that particles produced by the rotation device can be kept away from the substrate. It is also possible to provide different gas atmospheres in the partial chambers without the treatment of the substrate in the first partial chamber being affected by the gas located within the second partial chamber, which is particularly advantageous with gas-driven rotation.

Preferably, the separation element and the at least one rotating element are arranged relative to one another such that they do not touch, and the air gap surrounds the rotation axis of the rotating element, due to which the formation of particles caused by abrasion between the separation element and the at least one rotating element can be avoided.

With a preferred embodiment of the invention, the separation element and the at least one rotating element are no more than 5 mm apart from one another so as to limit the size of the air gap, and so also an exchange of gas between the partial chambers. Preferably, the air gap has a passage height of no more than 5 mm, with a maximum passage height of 3 mm, and in particular of 1 mm, being preferred. Besides the air gap, it is also possible for further gas passages to be provided between the first partial chamber and the second partial chamber, such further gas passages preferably being provided in the separation element. Via the air gap and the further gas passages, gas can be sucked from the first partial chamber into the second partial chamber. This is particularly advantageous if the first partial chamber contains so-called dead volume elements. These are understood as being volume elements which, in comparison to the other volume elements, only allow a very slow gas exchange, such as for example blind holes or other spatial indentations which only open to one side and which only allow a very slow flow of gas.

For good shielding of the substrate against particles which are produced by the rotation device, in one embodiment the rotation device is fully located within the process chamber. The rotation device preferably has at least one stationary part and one rotatable part, at least the stationary part being disposed in the second partial chamber so as to keep particles caused by friction between the parts away from the substrate.

The invention is particularly advantageous for a rapid heating system which has at least one gas nozzle on the stationary part and which is aligned to a surface of the rotatable part such that a gas flow emanating from the stationary part forms a cushion of gas for supporting the rotatable part and/or a rotational impulse. By separating the process chamber into two partial chambers, mixing of process gas and gas for producing the rotation is substantially eliminated such that the requirements for the gas to produce the rotation do not need to be so stringent. In particular, different gases can be used for the treatment of the substrate and for the rotation. To achieve acceleration and deceleration, preferably at least two gas nozzles are provided, the nozzles aligned to the surface of the rotatable part such that gas flows emanating therefrom produce rotational impulses in opposite directions. Preferably, the gas nozzles can be individually controlled. In order to prevent a flow of gas from the second partial chamber into the first, a control unit is preferably provided for controlling the quantity of gas fed per unit of time via the gas nozzle(s) directly to the second partial chamber such that this quantity is smaller than the quantity of gas discharged per unit of time via the at least one gas outlet open to the second partial chamber.

In order to produce a rotation of a rotatable part of the rotation device, means are preferably provided for producing a flow of gas along at least one contoured surface of a rotatable part of the rotation device such that a rotational impulse is produced.

With one embodiment of the invention, at least one rotating element of the rotation device covers an opening in the separation element so that the rotating element of the rotation device can serve as an additional separation element. In order to prevent the air gap between the separation element and the rotation device from affecting the thermal homogeneity of the substrate during the thermal treatment, the rotation device supports the substrate to be thermally treated in the process chamber such that its vertical parallel projection falls totally into the opening in the separation element. Preferably, the rotation device supports the substrate to be treated thermally in the process chamber such that the vertical parallel projection of the substrate to be treated thermally onto the plane of the separation element and the parallel projection of the air gap parallel to the projection direction of the substrate onto the same plane do not intersect at any point.

With a particularly preferred embodiment of the invention, the at least one heat source emits optical heat radiation, allowing fast and contact-free thermal treatment of the substrate. The heat source preferably comprises at least one halogen and/or at least one arc lamp. In this case, the separation element and/or at least one rotating disc of the rotation device is/are at least partially transparent to optical heat radiation of the heat source in order to make direct heating of the substrate possible with the heat radiation. For this, the separation element and/or at least one rotating disc of the rotation device can be made at least partially of quartz glass. However, the parts can also be made of sapphire, or of an ionic optically transparent crystal such as, for example, calcium fluoride. Preferably, the parts for optical radiation in the range of between 250 nm and 2500 nm are transparent. However, the parts can also be made at least partially of a metal, of graphite or SiC, or be made of a pure semiconductor such as Si or Ge, or of a compound semiconductor such as e.g. GaAs or InP. In particular, the parts of the separation element and/or of the rotation device are preferably optically transparent for the heat radiation of the heat source if they lie in a region of direct intervisibility between the heat source and the substrate.

In order to be able to have better control of the gas flow and/or the gas atmosphere in the first partial chamber, at least one further gas outlet open to the first partial chamber is provided.

The invention includes a method for the thermal treatment of substrates in a rapid heating system with a process chamber for accommodating a substrate, at least one heat source for heating the substrate, a rotation device for rotatably holding the substrate, and at least one separation element which divides the process chamber into two partial chambers such that the first partial chamber totally encloses the substrate to be thermally treated, and the second partial chamber encloses at least one part of the rotation device. In such method, the substrate is heated, a gas is conveyed into the first partial chamber via a gas inlet opening into the first partial chamber, and gas is discharged from the second partial chamber via a gas outlet opening to the second partial chamber, the gas flow in the process chamber being set such that a flow of gas from the second partial chamber to the first partial chamber is substantially prevented. In this way, the advantages already described above can be achieved.

In one embodiment of the invention, at least a first gas flow is conveyed over or along a surface of a rotatable element of the rotation device in order to set it in rotation. In order to decelerate the rotation, preferably at least one second gas flow is conveyed over or along a surface of a rotatable element of the rotation device. The first and/or second gas flow in the second partial chamber is preferably directed onto the surface of the rotatable element in order to thus limit particles produced/swirled up in the second partial chamber.

In a particularly preferred embodiment of the invention, a gas pressure in the second partial chamber is adjusted to a pressure which is less than the pressure in the first partial chamber in order to prevent gas and/or particles from the second partial chamber from passing into the first. In order to prevent gas and/or particles from the second partial chamber from passing into the first, a quantity of gas per unit of time, which is conveyed directly into the second partial chamber, is preferably smaller than a quantity of gas per unit of time which is discharged directly from the second partial chamber.

For improved control of the gas atmosphere in the first partial chamber, gas is preferably also discharged directly from the first partial chamber. In so doing, a quantity of gas per unit of time which is conveyed into the first partial chamber is preferably greater than a quantity of gas per unit of time which is discharged directly from the first partial chamber. In order to produce a positive flow of gas from the first partial chamber into the second partial chamber, during the thermal process, gas is preferably primarily sucked to the outside via the second partial chamber.

In order to avoid the process results being affected by the mixing of gases from the first and second partial chambers, substantially the same gas is preferably used for the rotation as is conveyed into the first partial chamber. For the rotation, preferably at least one gas from the following group is used: nitrogen, argon, oxygen, water vapor and hydrogen, or a gas mixture of at least two of the gases.

In a preferred embodiment of the invention, a pressure in the process chamber is set to a sub-atmospheric range of below 740 torr. Preferably the gas exchange between both partial chambers substantially only takes place via an air gap between the separation element and a rotating element of the rotation device.

According to a particularly preferred embodiment of the invention, max. 1% of a gas flow between the two partial chambers is directed from the second partial chamber to the first partial chamber.

Further embodiments of the invention are disclosed and described in the patent claims.

### BRIEF DESCRIPTION OF THE DRAWINGS

In the following, the invention is described in greater detail using preferred examples of embodiments with reference to the drawings. However, it is possible for a person skilled in the art to adopt embodiments and modifications without going beyond the spirit and scope of the invention. The device according to the invention can also advantageously be used in particular in connection with areas of application or methods other than those described here.

The drawings show as follows:

FIG. 1 illustrates a schematic cross-sectional view of a rapid heating system according to a first embodiment of the invention;

FIG. 2 illustrates a partially sectioned perspective view of the rapid heating system according to FIG. 1, wherein certain elements are omitted so as to simplify the illustration; and

FIGS. 3a to 3g show schematic examples of arrangements for a separation element and parts of a rotation device in a rapid heating chamber.

### DETAILED DESCRIPTION OF THE INVENTION, INCLUDING PREFERRED EMBODIMENTS

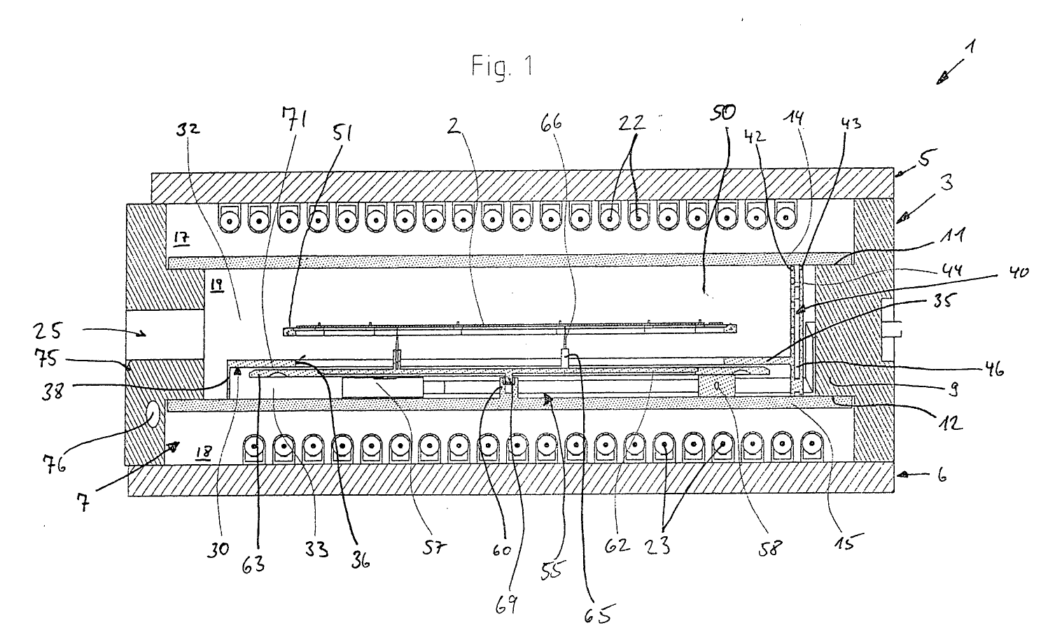

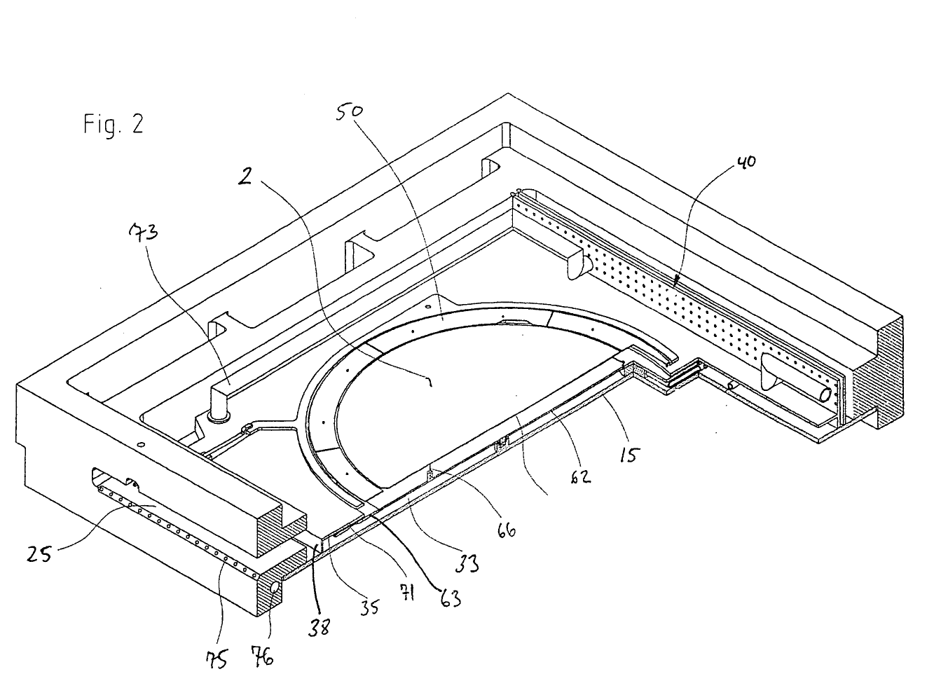

FIG. 1 schematically shows, in a cross-section, a preferred example of an embodiment of a rapid heating system 1, whereas FIG. 2 shows a partially sectioned perspective illustration of the rapid heating system 1. The rapid heating system 1 is provided for the thermal treatment of a disc-shaped substrate such as a semiconductor wafer.

In all of the figures, the same or similar components are identified with the same reference numbers. The relative terms used in the following description such as for example upper, lower etc. relate purely as examples to the representation in the figures and should not restrict the invention in any way.

The rapid heating system 1 has a frame-like main body 3, the upper and lower ends of which are covered by plate elements 5, 6 so as to form a rapid heating chamber 7.

The frame-like main body has an inwardly extending projection 9 which forms upper and lower circumferential contact surfaces 11 and 12. Upper and lower plate elements 14 and 15 lie on the contact surfaces 11 and 12 so as to form a seal, and are attached appropriately to the main body.

The plate elements 14, 15 divide the rapid heating chamber into an upper lamp chamber 17, a lower lamp chamber 18 and a process chamber 19 lying between the plate elements 14, 15. In the region of the upper lamp chamber 17, are plurality of heating lamps 22, such as for example halogen or arc lamps, are provided. Depending upon the area of application, all heating lamps 22 can be of the same type, or different types can also be provided.

In the region of the lower lamp chamber 18, a plurality of heating lamps 23 is provided, and these can be of the same type as the heating lamps 22 or of a different type.

The plate elements 14, 15 are substantially transparent for the heat radiation coming from the heating lamps 22, 23, and are, for example, made of quartz.

In one side of the frame-like main body 3 an insertion/removal opening 25 for loading and unloading the substrates into and from the process chamber 19 is provided. The insertion/removal opening 25 can be closed from the outside by means of a closure mechanism (not shown in detail).

Inside the process chamber 19 a separation element 30 is provided which divides the process chamber 19 into a first partial chamber 32 and a second partial chamber 33. The separation element 30 has a horizontal section 35 extending substantially parallel to the plate elements 14, 15 with a circular opening 36. Furthermore, the separation element 30 has a first attachment section 38 extending perpendicularly to the board element 15 and which extends between the horizontal section 35 and the lower plate element 15.

Furthermore, the separation element 30 has a gas inlet section 40 extending vertically substantially between the upper and lower plate elements 14, 15 on an end lying opposite the insertion/removal opening 25. The gas inlet section 40 is substantially formed by two vertically extending wall elements 42, 43, the wall element 42 facing the first partial chamber 32. A plurality of openings 44 is formed in the wall element 42, and these serve as a gas inlet for the process chamber 19. Between the wall elements 42, 43 a distribution chamber 46 is formed which can be subjected to a process gas via a feed (not shown in detail) in order to introduce a process gas into the first partial chamber 32 of the process chamber 19 via the openings 44 in the wall element 42.

In the region of the first partial chamber 32 a compensation ring 50 is provided which radially surrounds a substrate 2 accommodated within the process chamber and is supported by a holder 51. The compensation ring 50 is made up of a plurality of segments, at least one of which can be pivoted out of the plane of the substrate 2 so as to make it possible to access the substrate 2 using a handling mechanism. The compensation ring 50 is made of the same material as the substrate and serves to guarantee the most homogeneous heating possible of the substrate on the edge of the substrate.

In the region of the second partial chamber 33 a rotation device 55 is provided. The rotation device 55 has a stationary portion consisting of gas inlets 57, 58 and a retaining and bearing part 60 formed integrally with the lower plate element 15. Furthermore, the rotation device 55 has a rotating part comprising a circular plate segment 62 and an annular ring segment 63. The plate segment 62 lies on an inner circumferential edge of the ring segment 63 and can be attached appropriately to the ring segment 63. The plate segment 62 and the ring segment 63 form a substantially level surface.

On the upper side of the plate segment 62 a plurality of retainers 65 are provided for accommodating the substrate holding pins 66. The substrate holding pins 66 have an upwardly pointing support point for supporting the substrate 2. The substrate holding pins 66 thus only touch the substrate to be heated thermally at points and at just a few places.

Furthermore, the plate segment 62 has a downwardly pointing projection which forms a rotation shaft 69 of the rotation device 55. The rotation shaft 69 is accommodated in the retaining and bearing part 60 of the lower plate element 15, and is rotatably mounted therein.

The gas inlets 57, 58 are disposed below the ring segment 63, and they each have at least one gas nozzle which is directed onto a lower side of the ring segment 63. The nozzles of the gas inlets 57, 58 are directed onto the lower side of the ring segment 63 such that a flow of gas emanating therefrom produces a rotational impulse around the rotation shaft 69. The at least one nozzle of the gas inlet 57 is disposed here such that the flow of gas emanating therefrom produces a rotational impulse which is in the opposite direction to a rotational impulse which is produced by a gas flow emanating from the at least one nozzle of the gas outlet 58.

As well as producing a rotational impulse, it is also possible for the at least one nozzle of the gas inlets 57, 58 to provide a cushion of gas for supporting the ring segment 63 and the plate segment 62. In this case, the rotation shaft 69 will only provide a side bearing.

Although only two gas inlets 57, 58 are shown in FIG. 1, several gas inlets can of course also be provided, a flow of gas emanating from the gas outlets respectively being able to produce a cushion of gas and/or a rotational impulse.

Although the plate segment 62 and the ring segment 63 are shown as separate elements, they can of course also be formed as a one-part segment.

The ring segment 63 has an outer circumference which is greater than the inner circumference of the circular opening 36 in the horizontal section 35 of the separation element 30. The ring segment 63 and the horizontal section 35 therefore at least partially overlap. In this overlap region, an air gap 71 is formed between an upper side of the ring segment 63 and a lower side of the horizontal section 35, and this air gap connects the first partial chamber 32 of the process chamber 19 to the second partial chamber 33. The plate segment 62 and the ring segment 63 thus act as an additional separation element so as to separate the first and the second partial chambers from one another. In the region of the second partial chamber 33, a gas outlet (not shown in detail) is also provided which is connected to a gas outlet line 73 (FIG. 2).

In the region of the insertion/removal opening 25 a gas outlet is also provided which is directly connected to the first partial chamber 32 of the process chamber 19. The gas outlet is formed by a plurality of exhaust openings 75 in the main body 3 which are connected to an outlet line 76 formed in the main body 3. The gas outlet lines 73 and 76 are connected to respective suction devices, such as for example pumps, and in particular vacuum pumps. The suction devices can be controlled individually in order to control the quantities of gas sucked out of the first and second partial chambers.

Correspondingly, the gas inlet section 40 and the gas inlets 57, 58 are connected to respective individually controllable gas supplies so as to control a respective gas inlet in the first and second partial chambers 32, 33 of the process chamber 19.

A process gas is normally introduced into the first partial chamber 32 via the gas inlet section, although other gases, such as for example purge gases and/or inert gases, can also be introduced via the same.

The same or also different gases can be introduced into the second partial chamber via the gas inlets 57, 58, said gas inlets substantially serving to produce a rotational impulse for the rotation device 55.

In the following, the operation of the rapid heating system is briefly described by means of FIGS. 1 and 2.

A substrate 2, such as for example a semiconductor wafer, is loaded into the first partial chamber 32 of the process chamber 19 via an insertion/removal opening 25, and placed on the substrate holding pins 66. The insertion/removal opening 25 is then closed, and if appropriate, the process chamber is flushed by introducing a purge gas, such as for example an inert gas. Thermal treatment of the substrate 2 then takes place using a predetermined temperature/time profile whereby the heating lamps 22, 23 are used in the known manner in order to heat up the substrate 2. During this thermal treatment, a gas is conveyed to the ring segment 63 via at least one of the gas inlets 57 and/or 58 so as to set it in rotation. With the ring segment 63, the plate segment 62 and via this the substrate 2 are also set in rotation so as to facilitate even heating of the substrate 2 in the known manner.

A process gas is introduced into the first partial chamber 32 via the gas inlet section 40, and gas is sucked out via the gas outlet (not shown in detail) in the second partial chamber 33. At least as much gas is sucked out here via the gas outlet (not shown) as is introduced into the second partial chamber via the gas inlets 57, 58. Preferably, more gas is sucked out of the second partial chamber via the gas outlet (not shown) than is introduced via the gas inlets 57, 58. In this way, a flow of gas is produced in the direction leading from the first partial chamber 32 to the second partial chamber 33, and this prevents particles produced by the rotation device, such as for example abrasion particles in the region of the retaining and bearing part 60, from passing from the second partial chamber into the first partial chamber. Particle flow from the second to the first partial chamber can substantially be prevented even when only as much gas is sucked out of the second partial chamber 33 as is introduced via the gas inlets 57, 58 by means of the narrow air gap 71 between the ring segment 63 and the horizontal section 35 of the separation element 30. During the thermal treatment, the pressure in the two partial chambers of the process chamber can be in the atmospheric region of between 740 and 780 torr and also in the sub-atmospheric region of below 740 torr.

If gas inlets and gas outlets are to be found both in the first partial chamber as well as in the second partial chamber, by means of appropriate regulation of the supply and discharge of gas, it is preferably ensured that an at least differentially small difference in pressure occurs between the first and the second partial chambers such that during a thermal process, the pressure in the first partial chamber is always greater than the pressure in the second partial chamber so that the flow of gas through passages between the first partial chamber and the second partial chamber can substantially only take place from the first partial chamber towards the second partial chamber.

In an embodiment of a gas-driven rotation (not shown in detail), the rotation gas is introduced via at least a first, a second and a third gas inlet into the second partial chamber. Preferably, the first gas inlet forms a cushion of air or an air bearing here for the rotating element, the second gas inlet sets the rotation in motion and accelerates it, and the third gas inlet decelerates the rotation set in motion again. However, the disadvantage of this system is that after the cushion of air has been formed, the at least second and third gas inlets which accelerate and decelerate the rotation, must in addition be constantly opened and closed again in order to set the rotation in motion, guarantee a constant rotation speed, and decelerate the rotation again. However, by opening and closing gas inlets, additional particles occur due to sudden changes in flow, and these particles could be swirled onto the substrate to be thermally treated.

A preferred embodiment of the invention therefore makes possible active regulation of the rotation speed (closed loop) in that the gas inlets, which bring about the acceleration and deceleration of the rotation, also at the same time form the cushion of air for the rotating parts of the rotation device. In this way additional gas inlets, which only form a cushion of air, can be dispensed with. The acceleration of the rotation, the keeping the rotation speed constant, and the deceleration of the rotation happens with this structure in that with an acceleration, the quantity of gas per unit of time is increased for the acceleration by the gas inlets, or the flow of gas through the gas inlets is reduced for deceleration. Conversely, when decelerating, either the quantity of gas per unit of time via the gas inlets is increased for the deceleration, or the flow of gas via the gas inlets is reduced for the acceleration. With a constant rotation speed, a sufficient quantity of gas must be fed via the gas inlets, which bring about the acceleration and the deceleration of the rotation, such that the cushion of air between the fixed and the rotating parts of the rotation device supports the rotating parts. By means of a structure of this type, particles are prevented from being produced by suddenly switching on or switching off the supply of gas for the rotation gas.

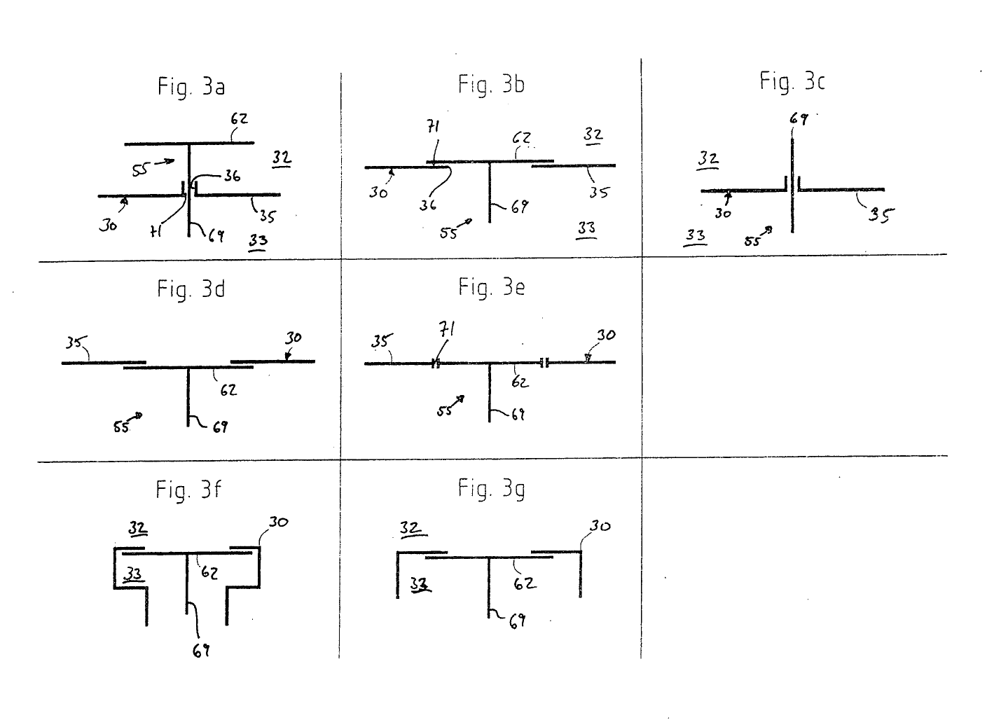

In order to prevent the movement of gas and/or particles from the second partial chamber towards the first partial chamber, different arrangements of the separation element 30 and the rotation device 55 are possible, some of which are shown in FIGS. 3a to 3g. According to FIG. 3a, in the region of the horizontal section 35 the separation element 30 only has a small passage opening 36 which is sufficient for allowing the rotation shaft 69 of the rotation device 55 to pass therethrough without contact. A plate segment 62 at the upper end of the rotation shaft 69 is located in the first partial chamber 32 and on this supports a substrate to be treated.

In this case, the plate segment 62 does not serve as an additional separation element between the first part-chamber 32 and the second partial chamber 33. A separation is substantially only formed by the separation element 30. In order to provide an improved separation, in the region of the circular opening 36 a flange extending parallel to the rotation shaft 69 can be provided so as to form a longitudinally extending air gap 71 between the rotation shaft 69 and the flange.

Otherwise, the structure of the rapid heating system can be as described with the previous example of an embodiment.

FIG. 3b shows a further variation of the arrangement of the separation element 30 and the rotation device 55. The separation element 30 once again has a horizontal section 35 with a circular opening 36. A rotation shaft 69 of the rotation device 55 extends from the second partial chamber 33, through the opening 36, and into the first partial chamber 32. On the upper end of the rotation shaft 69 a plate segment 62 is attached which has an outer circumference which is greater then the inner circumference of the circular opening 36. The horizontal section 35 and the plate segment 62 thus overlap. The plate segment 62 is held by the rotation shaft 69 a small distance above the horizontal section 35 so that a small air gap 71 is formed between these two elements.

FIG. 3c shows a further variation of an arrangement between the separation element 30 and the rotation device 55. This arrangement variation substantially corresponds to the arrangement variation according to FIG. 3a, the rotation device 55 not, however, having a plate segment at the upper end of the rotation shaft 69. At the upper end of the rotation shaft 69, any suitable support unit can be provided for supporting the substrate 2.

FIG. 3d shows a variation of an arrangement between the separation element 30 and the rotation device 55 which substantially corresponds to the variation according to FIGS. 1 and 2, a one-part plate segment 62 being provided however.

FIG. 3e shows a further variation of an arrangement between the separation element 30 and the rotation device 55. With this arrangement variation the separation element 30 once again has a horizontal section 35 with a circular opening. In the region of the circular opening, on the same plane as the plane of the horizontal section 35, a plate segment 62 of the rotation device 55 is provided which is supported in this position by a rotation shaft 69. The plate segment 62 has an outer circumference which is smaller than the inner circumference of the circular opening. On the outer circumference of the plate segment 62 a flange extending substantially perpendicularly to the same is provided. A corresponding flange is also provided on the inner circumference of the circular opening such that a corresponding air gap 71 is formed between these flanges, the length of which is greater than the thickness of the horizontal section 35 of the separation element 30 and the thickness of the plate segment 62. Although flanges are provided on the outer circumference of the plate segment 62 and on the inner circumference of the separation element 30, these can also be omitted.

FIGS. 3f and 3g shown variations of arrangements between the separation element 30 and the rotation device which substantially correspond to the arrangement variation according to FIGS. 1 and 2. However, the separation element 30 has special forms for reducing the volume of the second partial chamber 33.

In FIGS. 3a to 3g only one rotation shaft and, where appropriate, one plate segment 62 of the rotation device 55 were respectively shown. The structure of the other components can be similar to the example of an embodiment according to FIGS. 1 and 2, but it is also possible to provide an alternative drive for the rotation shaft 69.

In the examples of embodiments according to FIGS. 1, 2, 3b and 3d to 3g, the substrate respectively has an outer circumference which is smaller than the inner circumference of the circular opening. Furthermore, for the thermal treatment, the substrate is respectively arranged such that its parallel projection lies fully within the region of the circular opening 36. In the case of FIG. 3e, the parallel projection of the substrate to be treated lies fully within the region of the plate segment 62. In this way, the parallel projection and the air gap 71 are prevented from intersecting on any plane. In all examples of embodiments, the air gap has a width and height of max. 5 mm. In order to make it difficult for there to be an exchange of gas between the first and the second chambers, the air gap preferably has a width and height of max. 3 mm, and in particular of max. 1 mm.

The invention was described above in detail by means of preferred examples of embodiments, without being restricted to the precise examples of embodiments shown. In particular, alternative drive mechanisms for the rotation device can be provided. It is therefore possible, for example, for a rotation to be produced by a flow of gas from the first partial chamber into the second by means of corresponding contouring on the separation element and/or on the rotation shaft and/or on the plate segment in the region of the air gap. The rotation can also be driven, for example, mechanically, electrically, electromagnetically, magnetically or electrostatically. The separation element can also take on a wide variety of forms. As well as the air gap, it is also possible for further gas passages to be provided between the first partial chamber and the second partial chamber, for example in the separation element, through which gas can be sucked out from the first partial chamber into the second partial chamber. This is particularly advantageous if the first partial chamber contains so-called dead volume elements. These are understood as being volume elements which, in comparison to the other volume elements, only allow a very slow gas exchange, such as for example blind holes or other spatial indentations which are only open to one side, and which only allow a very slow flow of gas. If additional gas passages are provided in the separation element, these have a total passage area which is smaller than the passage area of the air gap.

The embodiments of the invention described can be supplemented or modified by elements and features which derive from a combination of elements and features of the disclosed embodiments, or which derive from exchanging elements and features of the disclosed embodiments with other elements and features.

The specification hereby incorporates by reference the disclosures of German priority document 10 2005 024 118.2, filed May 25, 2005 and U.S. Provisional Application No. 60/686,878, filed Jul. 6, 2005, in their entireties.

1. A rapid heating system for the thermal treatment of substrates comprising:
a process chamber divided into a first partial chamber and a second partial chamber by a separation element;
at least one heat source;
a rotation device configured to support and rotate a substrate such that the substrate is disposed entirely within the first partial chamber and the rotation device is enclosed at least partially within the second partial chamber;
at least one gas inlet disposed in the first partial chamber; and
at least one gas outlet disposed in the second partial chamber;
wherein the first and the second partial chambers are connected by a gap formed between the separation element and at least one rotating element of the rotation device.

2. The rapid heating system as set forth in claim 1, wherein the separation element and the at least one rotating element are arranged relative to one another such that they do not touch and the gap surrounds the rotation axis of the rotating element.

3. The rapid heating system as set forth in claim 1, wherein the separation element and the at least one rotating element are spaced no more than about 5 mm apart from one another.

4. The rapid heating system as set forth in claim 1, wherein the gap has a passage height of no more than about 5 mm.

5. The rapid heating system as set forth in claim 1, wherein the rotation device is fully located within the process chamber.

6. The rapid heating system as set forth in claim 1, wherein the rotation device has at least one stationary part and a rotatable part, and at least the stationary part is disposed in the second partial chamber.

7. The rapid heating system as set forth in claim 6, further comprising at least one gas nozzle on the stationary part of the rotation device, the gas nozzle aligned to a surface of the rotatable part of the rotation device such that a gas flow emanating from the nozzle imparts force on the rotatable part.

8. The rapid heating system as set forth in claim 7, comprising at least two gas nozzles which are directed onto the surface of the rotatable part such that the respective gas flows emanating from the nozzles impart rotational impulses of opposite directions on the rotatable part of the rotation device.

9. The rapid heating system as set forth in claim 8, wherein the gas nozzles are configured to be controlled individually.

10. The rapid heating system as set forth in claim 7, further comprising a control unit configured to control the quantity of gas fed per unit of time via the at least one gas nozzle directly to the second partial chamber.

11. The rapid heating system as set forth in claim 1, wherein the rotation device includes at least one contoured surface, and further comprising means for producing a flow of gas along the at least one contoured surface such that a rotational impulse is produced.

12. The rapid heating system as set forth in claim 1, wherein the rotation device comprises at least one rotating element that covers an opening in the separation element.

13. The rapid heating system as set forth in claim 12, wherein the rotation device is configured to support the substrate such that a vertical parallel projection of the substrate falls totally into the opening in the separation element.

14. The rapid heating system as set forth in claim 1, wherein the rotation device is configured to support the substrate such that a vertical parallel projection of the substrate onto the plane of the separation element, and the vertical parallel projection of the air gap onto the plane of the separation element do not intersect at any point.

15. The rapid heating system as set forth in claim 1, wherein the at least one heat source emits optical heat radiation.

16. The rapid heating system as set forth in claim 15, wherein the heat source comprises at least one lamp.

17. The rapid heating system as set forth in claim 15 wherein the separation element is at least partially transparent to radiation emitted from the heat source.

18. The rapid heating system as set forth in claim 17, wherein the separation element comprises quartz glass.

19. The rapid heating system as set forth in claim 15, wherein at least those parts of the separation element which lie in a region of direct intervisibility between the heat source and the substrate are at least partially optically transparent to radiation emitted from the heat source.

20. The rapid heating system as set forth in claim 1, comprising a plurality of heat sources positioned above and below a support plane for the substrate to be thermally treated.

21. The rapid heating system as set forth in claim 1, further comprising at least one further gas outlet which is open to the first partial chamber.

22. A method for the thermal treatment of substrates, the method comprising:
supporting a substrate using a rotation device;
heating the substrate in a process chamber, the process chamber divided into a first partial chamber enclosing the substrate and a second partial chamber enclosing at least part of the rotation device;
introducing a gas into the first partial chamber via a gas inlet opening into the first partial chamber; and
discharging gas from the second partial chamber via a gas outlet opening to the second partial chamber, the flow of gas in the process chamber being set such that a flow of gas from the second partial chamber to the first partial chamber is substantially prevented.

23. The method as set forth in claim 22, further comprising rotating the rotation device in a first direction by directing at least a first gas flow onto or along a surface of a rotatable element of the rotation device disposed within the second partial chamber.

24. The method as set forth in claim 23, further comprising directing at least one second gas flow over or along a surface of a rotatable element of the rotation device in order to apply rotational force in the direction opposite to the first direction.

25. The method as set forth in claim 23 wherein the gas flow in the second partial chamber is directed onto the surface of the rotatable element.

26. The method as set forth in claim 22 wherein the gas pressure in the second partial chamber is maintained at a lower level than the gas pressure in the first partial chamber.

27. The method as set forth in claim 22, wherein the quantity of gas per unit of time introduced directly into the second partial chamber is smaller than the quantity of gas per unit of time which is discharged directly from the second partial chamber.

28. The method as set forth in claim 22, wherein gas is also discharged directly from the first partial chamber.

29. The method as set forth in claim 28, wherein the quantity of gas per unit of time introduced into the first partial chamber is greater than the quantity of gas per unit of time discharged directly from the first partial chamber.

30. The method as set forth in claim 22, wherein the substrate is heated from above and from below.

31. The method as set forth in claim 22, further comprising removing gas from the chamber, wherein the gas is primarily removed via an outlet in the second partial chamber.

32. The method as set forth in claim 23, wherein the same gas that is introduced into the first partial chamber is used to rotate the rotation device.

33. The method as set forth in claim 23, wherein the gas used for rotation comprises at least one gas selected from the following group: nitrogen, argon, oxygen, water vapor, and hydrogen.

34. The method as set forth in claim 22, wherein the pressure in the process chamber is set to a sub-atmospheric range of below about 740 torr.

35. The method as set forth in claim 22, wherein any gas exchange between the partial chambers substantially takes place via a gap between the separation element and a rotating element of the rotation device.

36. The method as set forth in claim 22, wherein gas flow from the second to the first partial chamber does not exceed 1% of the total gas flow between the first and second partial chambers.
